(19) United States
(12) Patent Application Publication
(10) Pub. No.: US 2026/0262471 A1
(43) Pub. Date: Sep. 3, 2026

(54) ELECTROSTATIC CHUCK

(71) Applicant: TOTO LTD., Fukuoka (JP)

(72) Inventors: Yuki SASAKI, Fukuoka (JP); Jun SHIRAISHI, Fukuoka (JP); Ikuo ITAKURA, Fukuoka (JP); Rui IMOTO, Fukuoka (JP); Hironori HAMASHIMA, Fukuoka (JP)

(73) Assignee: TOTO LTD., Fukuoka (JP)

(21) Appl. No.: 19/459,856

(22) Filed: Jan. 26, 2026

(30) Foreign Application Priority Data
Mar. 3, 2025 (JP) 2025-032856

(51) Int. Cl. H10P 72/72; H01J 37/32

(52) U.S. Cl. CPC H10P 72/722; H01J 37/32568; H01J 37/32577; H01J 37/32715

(57) ABSTRACT

An electrostatic chuck in which electrical connection between an internal electrode and a feed terminal can be easily achieved is provided. An electrostatic chuck 10 includes a dielectric substrate 100, an RF electrode 140 provided inside the dielectric substrate 100, a feed terminal 170 arranged on an inner side of a recessed section 160 which is formed on a surface 120 opposite to a placement surface in the dielectric substrate 100, and a connection section 190 configured to electrically connect the RF electrode 140 with the feed terminal 170. In this electrostatic chuck 10, a distance T from a bottom 161 of the recessed section 160 to the RF electrode 140 is larger than 0.05 mm.

### CROSS-REFERENCE TO RELATED APPLICATION

This application is based upon and claims the benefit of priority from Japanese Patent Application No. 2025-032856 filed on March 3, 2025, the entire contents of which are incorporated herein by reference.

### FIELD

The present invention relates to an electrostatic chuck.

### BACKGROUND

For example, in a semiconductor manufacturing apparatus including an etching apparatus, an electrostatic chuck is provided as an apparatus configured to attract and hold a wafer such as a silicon wafer to be processed. The electrostatic chuck includes a dielectric substrate to which an attraction electrode is provided and a base plate which supports the dielectric substrate, and has a configuration in which these are joined to each other. When a voltage is applied to the attraction electrode, an electrostatic force is generated, and the wafer placed on the dielectric substrate is attracted and held.

An internal electrode is provided inside the dielectric substrate. The "internal electrode" is, for example, the attraction electrode described above. An RF electrode serving as one of a pair of counter electrodes configured to generate plasma in the semiconductor manufacturing apparatus may be provided as the "internal electrode" inside the dielectric substrate.

A feed terminal is further provided in the dielectric substrate. The feed terminal is a conductive member for receiving electric power supplied to the internal electrode from the outside. As described in Japanese Patent No. 7184034, the feed terminal is often arranged on an inner side of a recessed section that is formed on a surface opposite to a placement surface in the dielectric substrate.

### SUMMARY

As a specific configuration for electrically connecting the internal electrode with the feed terminal, for example, it can be considered that the above-described recessed section is formed so that the internal electrode is exposed at a bottom, and the feed terminal arranged on the inner side of the recessed section is directly connected to the exposed internal electrode. However, in a case of making such a configuration, a depth of the recessed section needs to be precisely adjusted, so that there is the problem that it is extremely difficult to process the recessed section.

Thus, the present inventors have been examining a configuration in which the above-described recessed section is formed to a depth that does not reach the internal electrode, and the bottom of the recessed section and the internal electrode are electrically connected by, for example, a via. However, when manufacturing the electrostatic chuck having such a configuration, a new problem may occur in which a bottom part of the recessed section cracks when forming the recessed section or the via.

The present invention has been made in view of such a problem and aims at providing an electrostatic chuck in which electrical connection between the internal electrode and the feed terminal can be easily achieved.

To solve the problem described above, the electrostatic chuck according to the present invention includes a dielectric substrate including a placement surface on which an object to be attracted is placed, an internal electrode provided inside the dielectric substrate, a feed terminal that is arranged on an inner side of a recessed section formed on a surface opposite to the placement surface in the dielectric substrate, and a connection section configured to electrically connect the internal electrode with the feed terminal. In this electrostatic chuck, a distance from the bottom of the recessed section to the internal electrode is larger than 0.05 mm.

In the electrostatic chuck having the above-described configuration, by making a distance from the bottom of the recessed section to the internal electrode larger than 0.05 mm, it is possible to prevent the part from cracking when forming the recessed section, the connection section and the light. Due to this, electrical connection between the internal electrode and the feed terminal can be easily achieved without damaging the dielectric substrate and the like.

According to the present invention, it is possible to provide an electrostatic chuck in which electrical connection between the internal electrode and the feed terminal can be easily achieved.

### BRIEF DESCRIPTION OF THE DRAWINGS

FIG. 1 is a cross sectional view schematically illustrating a configuration of an electrostatic chuck according to a first embodiment;

FIG. 2 is an enlarged view illustrating a configuration of a feed terminal and its neighboring part of the electrostatic chuck according to the first embodiment;

FIG. 3 is a diagram illustrating the feed terminal, a connection section, and the like viewed from a direction perpendicular to a placement surface;

FIG. 4 is a diagram for explaining a method of manufacturing the electrostatic chuck according to the first embodiment;

FIG. 5 is a diagram for explaining a method of manufacturing the electrostatic chuck according to the first embodiment;

FIG. 6 is a diagram for explaining a method of manufacturing the electrostatic chuck according to the first embodiment;

FIG. 7 is a cross sectional view schematically illustrating a configuration of an electrostatic chuck according to a second embodiment;

FIG. 8 is a perspective view illustrating a configuration of a connection member included in the electrostatic chuck according to the second embodiment;

FIG. 9 is an enlarged view illustrating a configuration of a feed terminal and its neighboring part of an electrostatic chuck according to a third embodiment;

FIG. 10 is a diagram for explaining a method of manufacturing the electrostatic chuck according to the third embodiment; and

FIG. 11 is a diagram illustrating a configuration of an electrostatic chuck according to a comparative example.

### DETAILED DESCRIPTION

Hereinafter, the present embodiment will be described with reference to the accompanying drawings. To ease understanding of the descriptions, in each drawing, the same components are denoted by the same reference signs as much as possible, and duplicate descriptions are not repeated.

A first embodiment will be described. An electrostatic chuck 10 according to the present embodiment is configured to attract and hold a wafer W set as a process target by an electrostatic force inside a semiconductor manufacturing apparatus such as, for example, an etching apparatus which is not illustrated in the drawing. The wafer W that is an object to be attracted is, for example, a silicon wafer. The electrostatic chuck 10 may be used in an apparatus other than the semiconductor manufacturing apparatus.

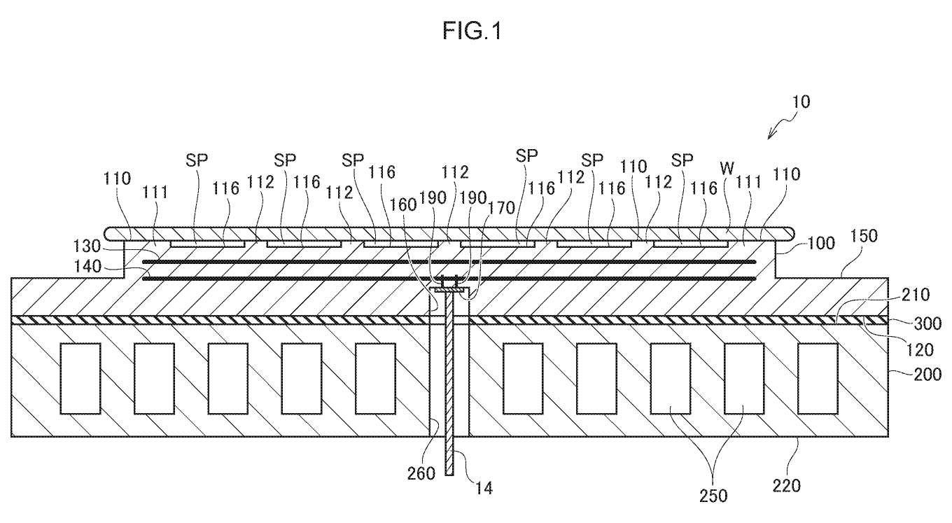

FIG. 1 is a cross sectional view schematically illustrating a configuration of the electrostatic chuck 10 in a state in which the wafer W is attracted and held. The electrostatic chuck 10 includes a dielectric substrate 100 and a base plate 200.

The dielectric substrate 100 is a substantially disk-shaped member formed of a ceramic sintered body. The dielectric substrate 100 contains, for example, highly pure aluminum oxide (Al₂O₃), but may contain other materials. A ceramics purity or type, an additive, or the like in the dielectric substrate 100 may be appropriately set by taking into account plasma resistance or the like needed for the dielectric substrate 100 in the semiconductor manufacturing apparatus.

A surface 110 on an upper side in FIG. 1 in the dielectric substrate 100 serves as a "placement surface" on which the wafer W is placed. A surface 120 on a lower side in FIG. 1 in the dielectric substrate 100 serves as a "surface to be joined" which is joined to the base plate 200 via a joining layer 300. A perspective in a case where the electrostatic chuck 10 is viewed from the surface 110 side along a direction perpendicular to the surface 110 will also be hereinafter expressed as "top view".

An attraction electrode 130 is embedded inside the dielectric substrate 100. The attraction electrode 130 is a thin planar layer made of a metallic material such as, for example, tungsten, and is arranged so as to be parallel to the surface 110. As a material of the attraction electrode 130, molybdenum, platinum, palladium, and the like may be used in addition to tungsten. When a voltage is applied to the attraction electrode 130 from an outside via a feed line which is not illustrated in the drawing, an electrostatic force is generated between the surface 110 and the wafer W, and according to this, the wafer W is attracted and held. As a configuration of the above-described feed line, various publicly known configurations can be adopted, for example. The single attraction electrode 130 may be provided as so-called a "monopolar" electrode as in the present embodiment, but may also include two attraction electrodes as so-called "bipolar" electrodes.

In addition to the above-described attraction electrode 130, an RF electrode 140 is embedded inside the dielectric substrate 100. The RF electrode 140 is provided as one of a pair of counter electrodes for generating plasma in the semiconductor manufacturing apparatus. The other of the counter electrodes is provided at a position on an upper side relative to the electrostatic chuck 10 in the semiconductor manufacturing apparatus. When a high-frequency alternating-current voltage is applied between these counter electrodes, plasma is generated on the upper side of the wafer W and used for processing such as film deposition and etching on the wafer W.

Similarly to the attraction electrode 130, the RF electrode 140 is a thin planar layer made of a metallic material such as, for example, tungsten. As a material of the RF electrode 140, molybdenum, platinum, palladium, and the like may be used in addition to tungsten. The RF electrode 140 is embedded at a position closer to the surface 120 side than the attraction electrode 130. Similarly to the attraction electrode 130, the RF electrode 140 is arranged so as to be parallel to the surface 110. The RF electrode 140 is a single electrode which is substantially circular in top view. The RF electrode 140 corresponds to an "internal electrode" according to the present embodiment.

Power supply from an external power source to the RF electrode 140 is performed via a power supply member 14 and a feed terminal 170. The power supply member 14 is a stick-shaped conductive member electrically connected to the external power source which is not illustrated in the drawing. The power supply member 14 is held by a holding mechanism which is not illustrated in the drawing in a state in which a distal end thereof abuts against the feed terminal 170. The power supply member 14 may be configured as a member which can be expanded or contracted due to elastic deformation. The number of power supply members 14 connected to the electrostatic chuck 10 may be only one, or may be multiple.

The feed terminal 170 is a terminal that is provided in the dielectric substrate 100 as a part for receiving electric power supplied to the RF electrode 140. The feed terminal 170 is a substantially disk-shaped member made of a conductive member such as metal, for example. As a material of the feed terminal 170, for example, a material containing molybdenum is used.

A recessed section 160 is formed on the surface 120 opposite to the placement surface in the dielectric substrate 100. The feed terminal 170 is arranged on an inner side of the recessed section 160, and electrically connected to the RF electrode 140 via a connection section 190 which will be described later. A specific configuration of the feed terminal 170 and its neighboring part will be described later.

A space SP is formed between the dielectric substrate 100 and the wafer W. When a process such as etching is performed in the semiconductor manufacturing apparatus, a helium gas for temperature regulation is supplied to the space SP from the outside via a gas hole which is not illustrated in the drawing. When the helium gas is caused to be present between the dielectric substrate 100 and the wafer W, a thermal resistance between the dielectric substrate 100 and the wafer W is regulated, and according to this, a temperature of the wafer W is maintained at an appropriate temperature. It is noted that the gas for temperature regulation to be supplied to the space SP may be a gas of a type different from helium.

A seal ring 111 and a dot 112 are provided on the surface 110 which serves as the placement surface, and the space SP described above is formed around the seal ring 111 and the dot 112.

The seal ring 111 is a wall which defines the space SP in a position corresponding to an outermost circumference. An upper end of the seal ring 111 serves as a part of the surface 110 and abuts against the wafer W. It is noted that the seal ring 111 may include a plurality of seal rings 111 provided so as to divide the space SP. With such a configuration, a pressure of the helium gas in each of the spaces SP can be individually regulated, and a surface temperature distribution of the wafer W during the process can be set to be close to uniformity.

A part denoted by reference sign "116" in FIG. 1 is a bottom of the space SP. Hereinafter, this part may also be referred to as a "bottom 116". The seal ring 111 is formed as a result of digging a part of the surface 110 to a position of the bottom 116 together with the dot 112 which will be described next.

The dot 112 is a circular protrusion which protrudes from the bottom 116. The dot 112 includes a plurality of dots 112 to be provided. The plurality of dots 112 are substantially uniformly distributed and arranged on the placement surface of the dielectric substrate 100. An upper end of each of the dots 112 becomes a part of the surface 110 and abuts against the wafer W. By providing the plurality of thus configured dots 112, warping of the wafer W is reduced.

The dielectric substrate 100 of the present embodiment is provided with a rim portion 150. The rim portion 150 is a part protruding further toward the outer peripheral side relative to the surface 110 serving as the placement surface. In top view, the rim portion 150 surrounds the entire surface 110 from an outer side. A surface on the wafer W side (surface on the upper side in FIG. 1) in the rim portion 150 is in a position on the base plate 200 side (lower side in FIG. 1) relative to the surface 110. When the wafer W is processed, an annular member referred to as a "focus ring" or the like which is not illustrated in the drawing is placed on the rim portion 150. Instead of such an aspect, an aspect may be adopted in which the above-described annular member is directly placed on the base plate 200 without the provision of the rim portion 150 in the dielectric substrate 100.

The base plate 200 is a substantially disk-shaped member which supports the dielectric substrate 100. The base plate 200 is made of, for example, a metallic material such as aluminum. The base plate 200 is joined to the surface 120 of the dielectric substrate 100 via the joining layer 300. A surface 210 on the upper side in FIG. 1 in the base plate 200 serves as a "surface to be joined" which is joined to the dielectric substrate 100.

The joining layer 300 is a layer provided between the dielectric substrate 100 and the base plate 200 to join those components. The joining layer 300 is obtained by causing an adhesive made of an insulating material to be cured. In the present embodiment, a silicone adhesive is used as the above-described adhesive. It is noted however that the joining layer 300 may be obtained by causing an adhesive of other types to be cured. In any case, in order that a thermal resistance between the dielectric substrate 100 and the base plate 200 is reduced, a material with a highest possible thermal conductivity is preferably used as the material of the joining layer 300.

An insulating film may be formed on a surface of the base plate 200. As the insulating film, for example, an alumina film formed by thermal spraying can be used. When the surface of the base plate 200 is covered by the insulating film, it is possible to increase dielectric withstand voltage of the base plate 200.

A coolant flow path 250 through which a coolant flows is formed inside the base plate 200. When the process such as etching is performed in the semiconductor manufacturing apparatus, the coolant is supplied from the outside to the coolant flow path 250, and according to this, the base plate 200 is cooled down. Heat generated in the wafer W during the process is transferred to the coolant via the helium gas in the space SP, the dielectric substrate 100, and the base plate 200, and the heat is exhausted to the outside together with the coolant. The supply and exhaustion of the coolant to and from the coolant flow path 250 are performed via openings which are not illustrated in the drawing and which are formed in a surface 220 opposite to the surface 210 in the base plate 200.

A through hole 260 is formed in the base plate 200. The through hole 260 is a hole which is provided for inserting the power supply member 14 described above, and is formed so as to perpendicularly pass through the base plate 200 from the surface 210 to the surface 220. A cylindrical member may be arranged between an inner surface of the through hole 260 and the power supply member 14 for preventing an electric discharge from being caused therebetween.

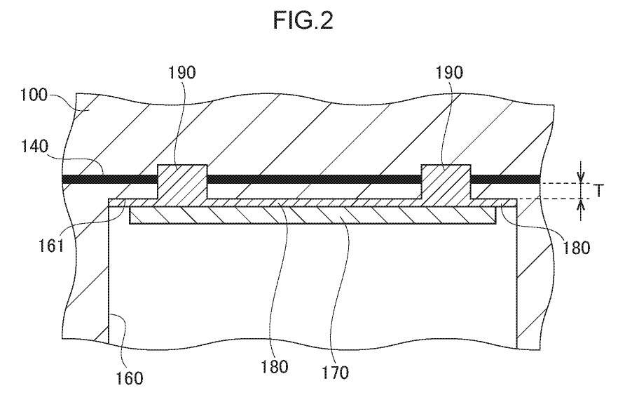

FIG. 2 illustrates a specific configuration of the feed terminal 170 and its neighboring part in the electrostatic chuck 10 illustrated in FIG. 1. The power supply member 14 is not illustrated in FIG. 2.

As described above, the recessed section 160 is formed on the surface 120 of the dielectric substrate 100. An outer shape of the recessed section 160 in top view is a circular shape. The recessed section 160 is a bottomed hole which is formed so as to be recessed toward the surface 110 side from the surface 120. A diameter of the recessed section 160 (which can be also referred to as an inner diameter of the recessed section 160) in top view is slightly larger than an outer diameter of the feed terminal 170 in top view.

A bottom of the recessed section 160, that is, a surface of the recessed section 160 closest to the surface 110, is also referred to as a "bottom 161" hereinafter. The feed terminal 170 is joined to the bottom 161 of the recessed section 160 via a brazing filler metal 180. The brazing filler metal 180 is obtained by adding titanium to a silver brazing filler metal, for example, and can be directly brazed to the surface of the dielectric substrate 100 made of ceramics. The brazing filler metal 180 may contain copper and the like in addition to silver or titanium.

A position of the bottom 161, that is, a position where the feed terminal 170 is joined, is a position closer to the surface 120 side than the RF electrode 140. The RF electrode 140 and the feed terminal 170 are electrically connected to each other via the connection section 190. The connection section 190 is formed so as to extend from the bottom 161 of the recessed section 160 toward the surface 110 (upper side in FIG. 2), and extends to a position closer to the surface 110 side than the RF electrode 140. That is, the connection section 190 passes through the RF electrode 140, and is electrically connected to the RF electrode 140. An end part of the connection section 190 on the lower side in FIG. 2 is connected to the brazing filler metal 180. In the present embodiment, a material of the connection section 190 and a material of the brazing filler metal 180 are the same, and the connection section 190 and the brazing filler metal 180 are integrally connected to each other. With the configuration as described above, the RF electrode 140 and the feed terminal 170 are electrically connected to each other via the brazing filler metal 180 and the connection section 190.

In FIG. 2, "T" represents a distance from the bottom 161 of the recessed section 160 to the RF electrode 140. The distance will also be hereinafter referred to as a "distance T". In the present embodiment, the distance T is larger than 0.05 mm.

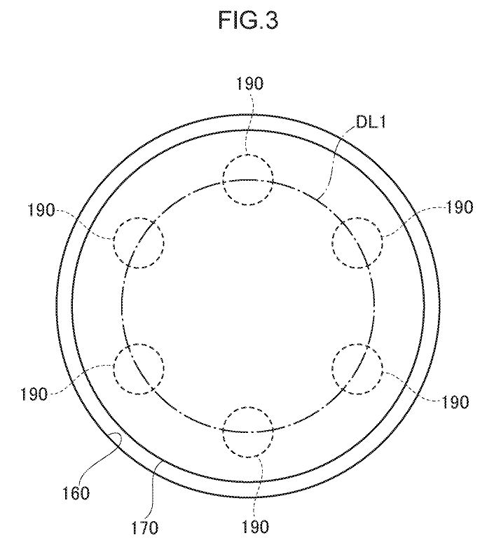

FIG. 3 schematically illustrates a part where the recessed section 160 is formed in the dielectric substrate 100 viewed from the surface 120 side. In FIG. 3, the connection section 190 on a deeper side of the drawing than the feed terminal 170 is depicted by a dotted line. In the present embodiment, a plurality of the connection sections 190 are connected to the one feed terminal 170. A shape of each of the connection sections 190 in top view is a circular shape.

In top view, the plurality of connection sections 190 are arranged side by side in a circular shape on the inner side of the recessed section 160. A circular dot-and-dash line DL1 in FIG. 3 represents a virtual circle passing through centers of the respective connection sections 190 in top view. That is, the plurality of connection sections 190 are arranged side by side along the circle of the dot-and-dash line DL1. A center of this circle in top view matches a center of the recessed section 160.

Furthermore, in the present embodiment, the plurality of connection sections 190 are arranged side by side at regular intervals along the circle of the dot-and-dash line DL1. The "interval" herein means a length along the dot-and-dash line DL1 between a pair of the connection sections 190 adjacent to each other. All of the plurality of connection sections 190 may be arranged side by side at regular intervals along the circle of the dot-and-dash line DL1, or only some of the plurality of connection sections 190 may be arranged in such a manner.

Another different connection section 190 may be provided at a position different from the above-described positions. For example, the connection section 190 may be separately provided at a position which is the center of the circle of the dot-and-dash line DL1 in top view.

In the method of manufacturing the electrostatic chuck 10, a method for forming the connection section 190 and the like will be specifically described. First, the dielectric substrate 100 incorporating the attraction electrode 130 and the RF electrode 140 is manufactured. As the manufacturing method thereof, various methods which are conventionally known such as sheet lamination, for example, can be adopted.

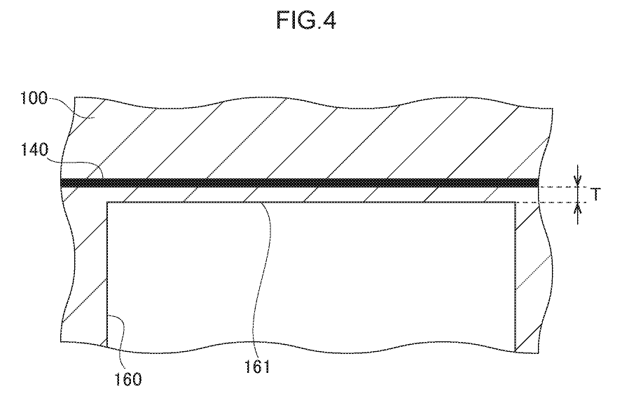

After firing of the dielectric substrate 100 is completed, the recessed section 160 is formed on the surface 120. FIG. 4 illustrates a cross section of the dielectric substrate 100 at the time when formation of the recessed section 160 is completed. The recessed section 160 is not formed up to a depth position reaching the RF electrode 140. As described above, the position of the bottom 161 of the recessed section 160 is a position closer to the surface 120 side than the RF electrode 140. Due to this, the RF electrode 140 is not exposed on an inner surface of the recessed section 160.

In forming the recessed section 160, it is preferable to form it to a depth position where the above-described distance T is larger than 0.05 mm. By making a thickness of a part of the dielectric substrate 100 between the bottom 161 and the RF electrode 140 larger than 0.05 mm, mechanical strength of the part can be ensured. According to experiments and the like conducted by the present inventors, it has been confirmed that, if the distance T is made larger than 0.05 mm, it is possible to sufficiently prevent a situation in which the part of the bottom 161 cracks when forming the recessed section 160 or a recessed section 162 described later.

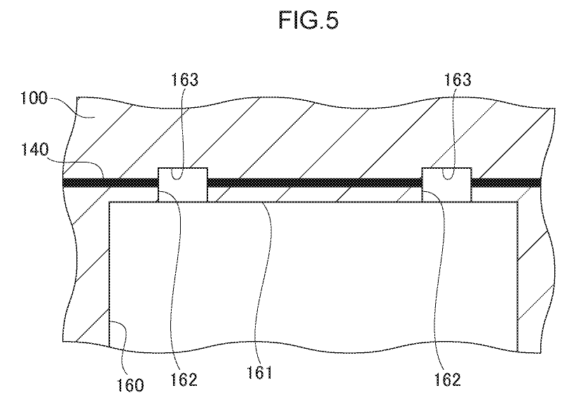

Subsequently, a plurality of recessed sections 162 are formed so as to extend from the bottom 161 of the recessed section 160 further toward the surface 110. FIG. 5 illustrates a state in which formation of the recessed sections 162 is completed. The recessed section 162 is a part which will be the connection section 190 later. A shape of each of the recessed sections 162 in top view is a circular shape.

A bottom of the recessed section 162, that is, a surface of the recessed section 162 closest to the surface 110, is also referred to as a "bottom 163" hereinafter. At the time when processing of the recessed section 162 is completed, the bottom 163 is present at a position closer to the surface 110 side than the RF electrode 140. That is, each of the recessed sections 162 is formed so as to extend to a depth position while passing through the RF electrode 140. Due to this, the RF electrode 140 is exposed on the inner surface of the recessed section 162.

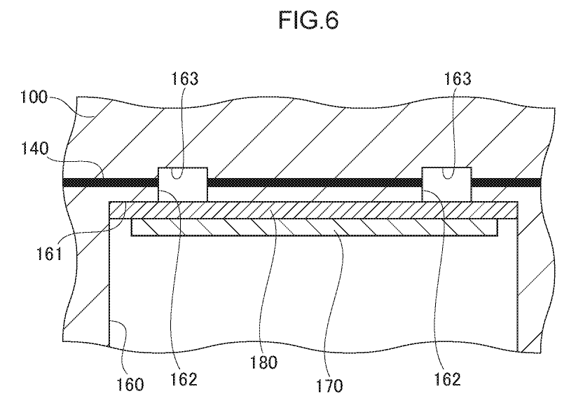

Subsequently, as illustrated in FIG. 6, the brazing filler metal 180 is arranged on the bottom 161 of the recessed section 160 first, and the feed terminal 170 is arranged thereafter. The brazing filler metal 180 is obtained by processing the brazing filler metal 180 having a plate shape before melting to have a circular shape. The brazing filler metal 180 in paste form may be applied to the bottom 161. At this point, the brazing filler metal 180 has not intruded into the recessed section 162, so that a space is formed inside the recessed section 162.

From the state in FIG. 6, the entire dielectric substrate 100 is heated by a vacuum furnace, for example. Due to this, the bottom 161, the feed terminal 170, and the like get wet due to the brazing filler metal 180 which is melted. Part of the melted brazing filler metal 180 intrudes into the inside of the recessed section 162. The inside of the recessed section 162 is filled with the brazing filler metal 180, and the RF electrode 140 exposed on the inner surface of the recessed section 162 and the brazing filler metal 180 are connected to each other.

After heating by the vacuum furnace is completed, the brazing filler metal 180 which has intruded into the inside of the recessed section 162 is solidified to be the connection section 190. Due to this, the electrostatic chuck 10 having the configuration illustrated in FIG. 2 is completed.

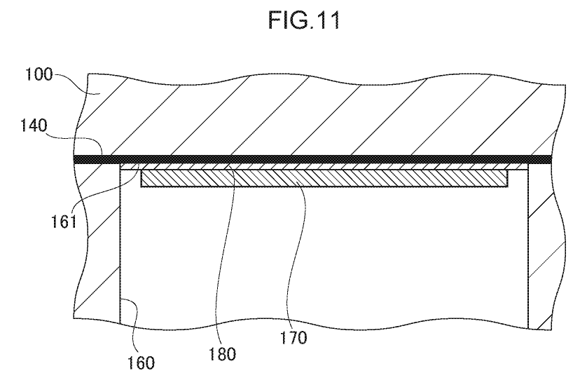

To explain an advantage of the configuration in the present embodiment as described above, first, the following describes a configuration according to a comparative example with reference to FIG. 11. As illustrated in FIG. 11, in this comparative example, the recessed section 160 is formed so that the RF electrode 140 is exposed at the bottom 161. Additionally, the feed terminal 170 is directly joined to the thus exposed RF electrode 140 via the brazing filler metal 180.

Also in the configuration of the comparative example, the RF electrode 140 and the feed terminal 170 can be electrically connected to each other. However, in forming the recessed section 160 on the dielectric substrate 100, a depth of the recessed section 160 needs to be precisely adjusted so that the RF electrode 140 which is relatively thin is exposed at the entire bottom 161. Due to this, there is the problem that it is extremely difficult to process the recessed section 160.

Thus, in the electrostatic chuck 10 according to the present embodiment, necessity of precisely adjusting the depth of the recessed section 160 is eliminated by adopting the configuration illustrated in FIG. 2.

As described above with reference to FIG. 4, for example, the recessed section 160 according to the present embodiment is not formed up to the depth position reaching the RF electrode 140. The position of the bottom 161 of the recessed section 160 does not need to be precisely adjusted so that the RF electrode 140 is exposed, so that the recessed section 160 can be relatively easily formed.

The same applies to formation of the recessed section 162 illustrated in FIG. 5. The position of the bottom 163 of the recessed section 162 does not need to be precisely adjusted so that the RF electrode 140 is exposed, so that the recessed section 162 can be relatively easily formed.

In this manner, in manufacturing the electrostatic chuck 10 according to the present embodiment, the depth of the recessed section 160 or the recessed section 162 does not need to be strictly adjusted in processing any of the recessed section 160 and the recessed section 162. Thus, electrical connection between the RF electrode 140 and the feed terminal 170 can be easily achieved.

In the present embodiment, the plurality of connection sections 190 are provided for the one feed terminal 170, so that the electrical resistance between the feed terminal 170 and the RF electrode 140 is reduced to be small. Additionally, the plurality of connection sections 190 are arranged side by side at regular intervals along the circle in top view, so that a current is prevented from flowing through some of the connection sections 190 in a biased manner. The current substantially uniformly flows through the plurality of connection sections 190, so that local heat generation can be prevented.

In the present embodiment, at the time when the bottom 161 is joined to the feed terminal 170 by the brazing filler metal 180, part of the brazing filler metal 180 intrudes into the recessed section 162 to be the connection section 190. Due to this, the connection section 190 can be easily formed.

As described above, when forming the recessed section 160 in the dielectric substrate 100, it is preferable to adjust the depth of the recessed section 160 so that the distance T from the bottom 161 to the RF electrode 140 is larger than 0.05 mm. More preferably, by making the distance T larger than 0.10 mm, it is possible to more reliably prevent a situation in which the part of the bottom 161 cracks.

However, if the distance T becomes larger than 0.4 mm, each of the connection sections 190 becomes longer, and an electrical resistance value thereof becomes so large that it cannot be ignored. As a result, Joule heat generated in the connection sections 190 is increased, and there is a concern that an adverse effect is exerted on the in-plane temperature distribution of the wafer W during processing. Thus, it is preferable to set the distance T to be smaller than 0.4 mm.

The configuration for performing power supply to the RF electrode 140 as described above, that is, the same configuration as the configuration including the recessed section 160, the feed terminal 170, the connection section 190, and the like, may be applied to a configuration for performing power supply to the attraction electrode 130. In a case where a heater is incorporated in the dielectric substrate 100, the same configuration as that of the present embodiment may be applied to a configuration for performing power supply to the heater.

A second embodiment will be described. Hereinafter, an aspect different from the first embodiment will be mainly described, and descriptions on an aspect common to the first embodiment are omitted as appropriate.

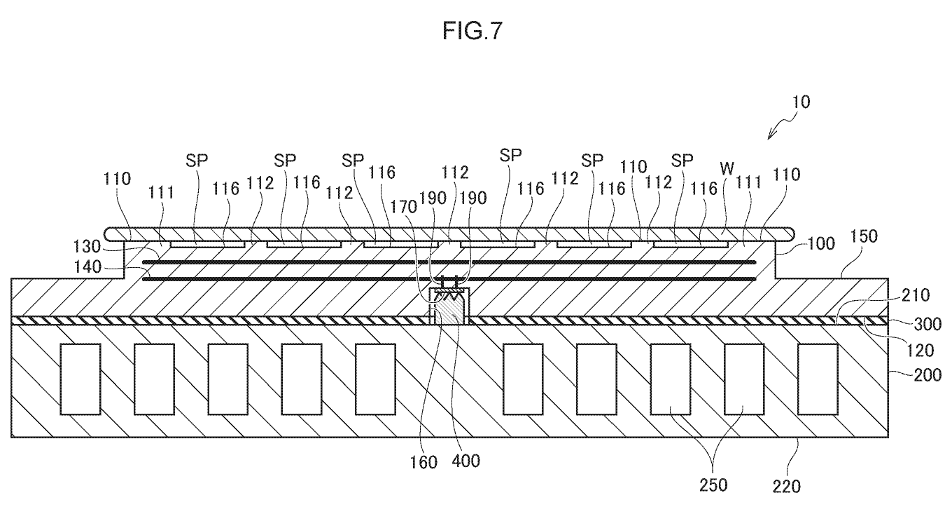

FIG. 7 schematically illustrates the configuration of the electrostatic chuck 10 according to the present embodiment as a cross sectional view similar to FIG. 1. In the present embodiment, power supply to the RF electrode 140 is not performed via the power supply member 14, but is performed via the base plate 200 and a connection member 400.

The connection member 400 is a member configured to electrically connect the RF electrode 140 with the base plate 200. Due to the connection member 400, a potential of the RF electrode 140 during the process on the wafer W becomes the same as a potential of the base plate 200. The potential of the base plate 200 is adjusted by an external power source, for example.

In the present embodiment, the through hole 260 is not formed in the base plate 200. Due to this, the inside of the recessed section 160 is a closed space. The connection member 400 is arranged inside this closed space.

The connection member 400 is a member of a substantially cylindrical shape which is formed of a fibrous metal member, and is accommodated inside the recessed section 160. One end of the connection member 400 abuts against the feed terminal 170 arranged in the recessed section 160. Another end of the connection member 400 abuts against the surface 210 of the base plate 200. The feed terminal 170 and the base plate 200 are electrically connected to each other by the thus arranged connection member 400. An aspect may be such that a recessed section as a bottomed hole is formed at a position immediately below the recessed section 160 in the surface 210 of the base plate 200, and part of the connection member 400 is accommodated in the recessed section. In a case where an insulating film is formed so as to cover the surface 210 of the base plate 200, it is only necessary to expose a metallic part of the base plate 200 without forming the insulating film at a part against which the connection member 400 abuts.

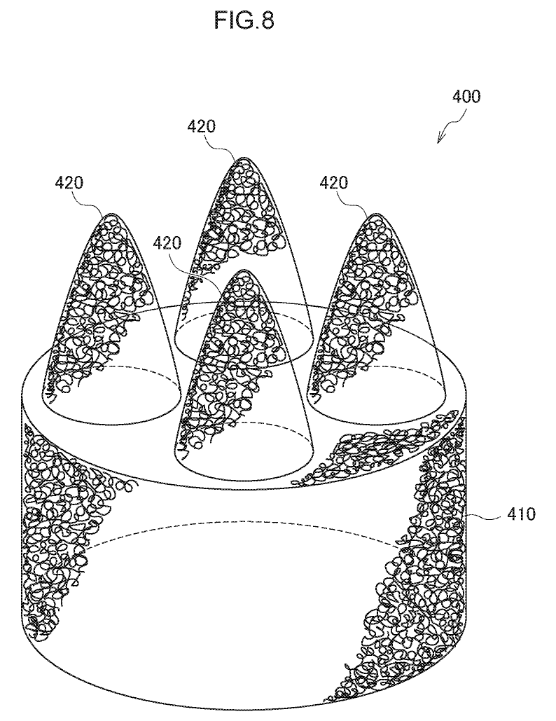

As illustrated in FIG. 8, the connection member 400 includes a main body section 410 of a substantially cylindrical shape and a plurality of protrusion sections 420, and an entirety thereof is integrally formed of the fibrous metal member. The protrusion section 420 is a protrusion of a substantially cylindrical shape which is formed so as to extend from the surface on the dielectric substrate 100 side in the main body section 410 further toward the dielectric substrate 100. In the present embodiment, four in total of the protrusion sections 420 are formed, but the number of the protrusion sections 420 may be different from four.

The connection member 400 formed of the fibrous metal member has a breathability to such an extent that allows air or a fluid such as an adhesive to intrude into the inside of the connection member 400. That is, the fibrous metal member is not sufficiently dense, and there is a gap between mutual fibers. When such a configuration is adopted, the connection member 400 serves as an elastic body in which each section including the protrusion section 420 may be easily deformed by an external force.

A dimension in an up and down direction (direction in which the protrusion section 420 extends) of the connection member 400 when the external force is not received is larger than a dimension in the same direction in the state of FIG. 7. That is, the connection member 400 is accommodated inside the recessed section 160 while being compressed along a direction from the dielectric substrate 100 toward the base plate 200, and is sandwiched between the feed terminal 170 and the surface 210. A distal end of each of the protrusion sections 420 is elastically deformed so as to collapse by being pressed against the feed terminal 170.

The connection member 400 is in a state of being pressed against each of the feed terminal 170 and the surface 210 by its own restoring force. For this reason, during the process on the wafer W or the like, even when thermal expansion or contraction occurs in each section of the electrostatic chuck 10, the electrical connection between the feed terminal 170 and the surface 210 is regularly maintained.

A shape different from that of the present embodiment may be adopted as the shape of the connection member 400. For example, the entirety of the connection member 400 may have a substantially cylindrical shape and a shape without the protrusion section 420.

Even with an aspect in which the feed terminal 170 and the base plate 200 are electrically connected to each other via the connection member 400 as in the present embodiment, the same effect as described in the first embodiment can be exhibited.

A third embodiment will be described. Hereinafter, an aspect different from the first embodiment will be mainly described, and descriptions on an aspect common to the first embodiment are omitted as appropriate.

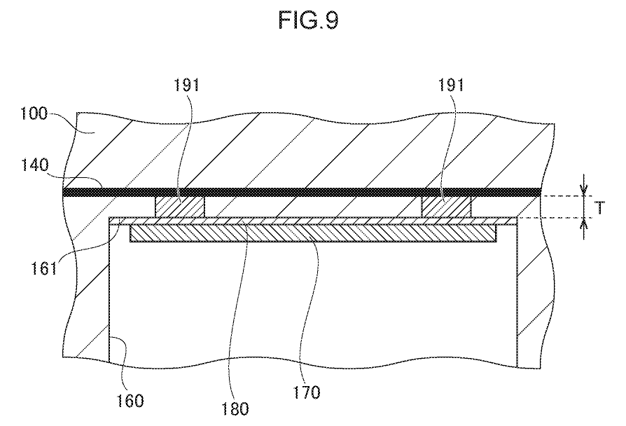

FIG. 9 schematically illustrates part of the configuration of the electrostatic chuck 10 according to the present embodiment as a cross sectional view similar to FIG. 2. In the present embodiment, electrical connection between the RF electrode 140 and the feed terminal 170 is made via a connection section 191 instead of the connection section 190. The connection section 191 is formed by filling, with a metallic material such as palladium, for example, an inside of a circular hole formed so as to extend from the bottom 161 to the RF electrode 140, and is also referred to as a so-called "via". In the present embodiment, a material of the connection section 191 and the material of the brazing filler metal 180 are different from each other. The connection section 191 is formed by using the same material as that of the RF electrode 140. A length of the connection section 191, that is, the distance T between the bottom 161 and the RF electrode 140, is also larger than 0.05 mm in the present embodiment.

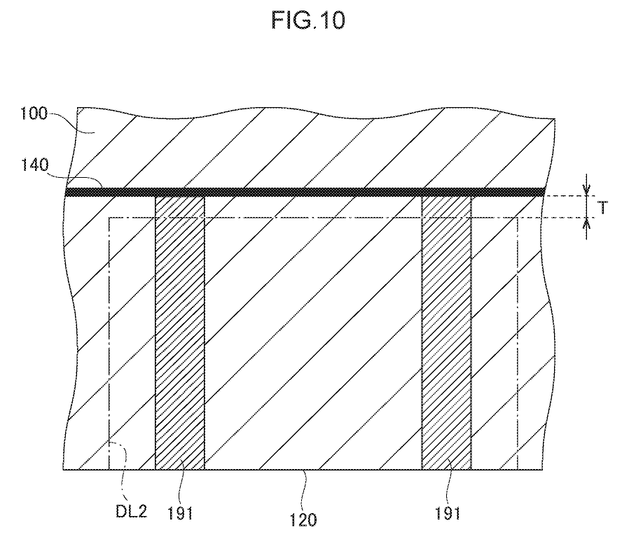

In the method of manufacturing the electrostatic chuck 10 according to the present embodiment, a method for forming the recessed section 160 and the like will be described. First, the dielectric substrate 100 incorporating the attraction electrode 130 and the RF electrode 140 is manufactured. At this time, the connection sections 191 are also formed. As illustrated in FIG. 10, each of the connection sections 191 is formed so as to extend in a linear shape from the RF electrode 140 to the surface 120. As the method of manufacturing the dielectric substrate 100 including the connection section 191 as described above, for example, various methods which are conventionally known such as sheet lamination can be adopted.

After firing of the dielectric substrate 100 illustrated in FIG. 10 is completed, the recessed section 160 is formed so as to extend from the surface 120 to the RF electrode 140. In FIG. 10, a range to be removed for forming the recessed section 160 is indicated by a dot-and-dash line DL2. In the present embodiment, similarly to the first embodiment, the recessed section 160 is not formed up to the depth position reaching the RF electrode 140. At the bottom 161 of the recessed section 160 formed in this manner, an end part of each of the connection sections 191 is exposed. After the recessed section 160 is completely formed, the brazing filler metal 180 is arranged so as to cover the bottom 161 of the recessed section 160, and the feed terminal 170 is arranged thereafter and heated in a vacuum furnace, thereby completing the electrostatic chuck 10 having the configuration illustrated in FIG. 9.

As in the present embodiment, in a case where the recessed section 160 is formed in the part where the connection section 191 is previously formed, it is preferable to set the distance T to be larger than 0.05 mm similarly to the first embodiment. Due to this, it is possible to prevent a situation in which the part of the bottom 161 cracks at the time of processing the recessed section 160, for example.

The present embodiment has been described above with reference to the specific examples. However, the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate including a placement surface on which an object to be attracted is placed;
an internal electrode provided inside the dielectric substrate;
a feed terminal arranged inside a recessed section formed on a surface opposite to the placement surface in the dielectric substrate; and
a connection section configured to electrically connect the internal electrode and the feed terminal to each other, wherein
a distance from a bottom of the recessed section to the internal electrode is larger than 0.05 mm.

2. The electrostatic chuck according to claim 1, wherein the distance from the bottom of the recessed section to the internal electrode is smaller than 0.4 mm.

3. The electrostatic chuck according to claim 1, wherein the connection section extends from the bottom of the recessed section toward the placement surface, and extends up to a position closer to the placement surface side than the internal electrode.
